(19) United States
(12) Patent Application Publication
(10) Pub. No.: US 2024/0324349 A1
(43) Pub. Date: Sep. 26, 2024

(54) DISPLAY APPARATUS

(71) Applicant: Samsung Display Co., LTD., Yongin-si (KR)

(72) Inventors: Myounggeun CHA, Yongin-si (KR); Sanggun CHOI, Yongin-si (KR); Keunwoo KIM, Yongin-si (KR)

(21) Appl. No.: 18/533,518

(22) Filed: Dec. 8, 2023

(30) Foreign Application Priority Data
Mar. 24, 2023 (KR) 10-2023-0039113
Jun. 7, 2023 (KR) 10-2023-0073141

(51) Int. Cl. H10K 59/131

(52) U.S. Cl. CPC H10K 59/131; H10K 59/1216

(57) ABSTRACT

A display apparatus includes a first transistor including a first semiconductor layer including a silicon semiconductor and a first gate electrode below the first semiconductor layer, where the first transistor controls a magnitude of a driving current flowing to a display element, a data line which transmits a data voltage, a second transistor including a second semiconductor layer including an oxide semiconductor, where the second transistor connects the data line to the first transistor in response to a scan signal, and a first capacitor including a first electrode and a second electrode, where the first electrode is disposed on the first semiconductor layer, and the second electrode at least partially overlaps the first electrode.

This application claims priority to Korean Patent Applications No. 10-2023-0039113, filed on Mar. 24, 2023, and Korean Patent Applications No. 10-2023-0073141, filed on Jun. 7, 2023, and all the benefits accruing therefrom under 35 U.S.C. § 119, the contents of which in their entireties are herein incorporated by reference.

### BACKGROUND

### 1. Field

One or more embodiments relate to a display apparatus.

### 2. Description of the Related Art

A display apparatus visually displays data. A display apparatus may be used as a display of a small-sized product, such as a cellular phone, or a display of a large-sized product, such as a television.

The display apparatus may include a plurality of pixels, which receive an electrical signal and then emit light, to display an image to the outside. Each pixel may include a display element. For example, an organic light-emitting display apparatus may include an organic light-emitting diode as a display element. Generally, an organic light-emitting display apparatus may include a thin-film transistor and an organic light-emitting diode on a substrate, and the organic light-emitting diode may directly emit light.

Recently, with the diversified usage of display apparatuses, various attempts have been made to improve the quality of display apparatuses.

### SUMMARY

One or more embodiments include a display apparatus with improved reliability.

According to one or more embodiments, a display apparatus includes a first transistor including a first semiconductor layer including a silicon semiconductor and a first gate electrode below the first semiconductor layer, where the first transistor controls a magnitude of a driving current flowing to a display element, a data line configured to transmit a data voltage, a second transistor including a second semiconductor layer including an oxide semiconductor, where the second connects the data line to the first transistor in response to a scan signal, and a first capacitor including a first electrode and a second electrode, where the first electrode is disposed on the first semiconductor layer, and the second electrode at least partially overlaps the first electrode.

In an embodiment, the second electrode may be electrically connected to the first gate electrode.

In an embodiment, the display apparatus may further include a sub-voltage line disposed on the second electrode and electrically connected to the first electrode.

In an embodiment, the first gate electrode, the first electrode, the second electrode, and the sub-voltage line may at least partially overlap each other.

In an embodiment, the display apparatus may further include a second capacitor including the first gate electrode and the first electrode and a third capacitor including the second electrode and the sub-voltage line, where the first capacitor, the second capacitor, and the third capacitor may be connected in parallel with each other.

In an embodiment, the second transistor may further include a second lower gate electrode below the second semiconductor layer and a second upper gate electrode above the second semiconductor layer.

In an embodiment, the second lower gate electrode may be disposed in a same layer as a layer in which the first electrode is disposed, and the second upper gate electrode may be disposed in a same layer as a layer in which the second electrode is disposed.

In an embodiment, the display apparatus may further include a display panel including a display area and a non-display area outside the display area, where the display area may include a first display area and a second display area at least partially surrounded by the first display area, and the first and second transistors may be disposed in the display area, and a component disposed below the display panel to correspond to the second display area.

In an embodiment, the display apparatus may further include a plurality of first display elements disposed in the first display area, a plurality of second display elements disposed in the second display area, a plurality of second sub-pixel circuits electrically connected to the plurality of second display elements, respectively, and a plurality of connection lines electrically connecting the plurality of second display elements with the plurality of second sub-pixel circuits, respectively, where the plurality of second sub-pixel circuits may be disposed between the first display area and the second display area or in the non-display area.

In an embodiment, the display apparatus may further include an emission control line which transmits an emission control signal, an initialization voltage line which transmits an initialization voltage, a fifth transistor which connects a driving voltage line to a side of the first semiconductor layer in response to the emission control signal, a sixth transistor which connects another side of the first semiconductor layer to an anode of the display element in response to the emission control signal, and a seventh transistor which connects the initialization voltage line to the anode of the display element in response to another scan signal.

In an embodiment, the fifth transistor may include a fifth semiconductor layer, the sixth transistor may include a sixth semiconductor layer, and the seventh transistor may include a seventh semiconductor layer. In such an embodiment, each of the fifth to seventh semiconductor layers may include the oxide semiconductor.

According to one or more embodiments, a display apparatus includes a display panel including a display area and a non-display area outside the display area, where the display area includes a first display area and a second display area at least partially surrounded by the first display area, and a component disposed below the display panel to correspond to the second display area, where the display panel includes a first transistor including a first semiconductor layer including a silicon semiconductor, where the first transistor controls a magnitude of a driving current flowing to a display element, a data line which transmits a data voltage, a second transistor including a second semiconductor layer including an oxide semiconductor, where the second transistor connects the data line to the first transistor in response to a scan signal, and a first capacitor including a first electrode and a second electrode, where the first electrode is disposed on the first semiconductor layer, and the second electrode is spaced apart from the first electrode.

In an embodiment, the first transistor may further include a first gate electrode below the first semiconductor layer.

In an embodiment, the display apparatus may further include a sub-voltage line disposed on the second electrode and electrically connected to the first electrode.

In an embodiment, the sub-voltage line may be electrically connected to a driving voltage line.

In an embodiment, the display apparatus may further include a second capacitor including the first gate electrode and the first electrode and a third capacitor including the second electrode and the sub-voltage line.

In an embodiment, the display apparatus may further include an emission control line which transmits an emission control signal, a first initialization voltage line which transmits a first initialization voltage, a second initialization voltage line which transmits a second initialization voltage, a fifth transistor which connects a driving voltage line to a side of the first semiconductor layer in response to the emission control signal, a sixth transistor which connects another side of the first semiconductor layer to an anode of the display element in response to the emission control signal, and a seventh transistor which connects the second initialization voltage line to the anode of the display element in response to another scan signal.

In an embodiment, the fifth transistor may include a fifth semiconductor layer, the sixth transistor may include a sixth semiconductor layer, and the seventh transistor may include a seventh semiconductor layer. In such an embodiment, each of the fifth to seventh semiconductor layers may include the oxide semiconductor.

In an embodiment, the display apparatus may further include a third transistor including a third semiconductor layer having a side connected to the first gate electrode and another side connected to the sixth semiconductor layer and a fourth transistor including a fourth semiconductor layer having a side connected to the first gate electrode and another side connected to the first initialization voltage line, where each of the third semiconductor layer and the fourth semiconductor layer may include the oxide semiconductor.

In an embodiment, the third semiconductor layer, the fourth semiconductor layer, and the sixth semiconductor layer may be integrally formed with each other as a single unitary and indivisible part.

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view of a display apparatus according to an embodiment;

FIGS. 2A and 2B are schematic cross-sectional views of a display apparatus according to an embodiment;

FIG. 3 is a schematic plan view of a display panel according to an embodiment;

FIGS. 4A and 4B are schematic equivalent circuit diagrams of a light-emitting diode and a sub-pixel circuit which are arranged in a display panel according to an embodiment;

FIG. 5 is a schematic plan view showing locations of transistors and a storage capacitor of a pixel included in a display apparatus according to an embodiment;

FIGS. 6 to 11 are schematic plan views showing a process of forming elements of the display apparatus illustrated in FIG. 5;

FIG. 12 is a schematic cross-sectional view of a display apparatus taken along line I-I′ of FIG. 5; and

FIG. 13 is a schematic cross-sectional view of a display apparatus taken along line II-II′ of FIG. 5.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

While the disclosure is capable of various modifications and alternative forms, embodiments thereof are shown by way of example in the drawings and will herein be described in detail. Effects and characteristics of the disclosure, and realizing methods thereof will become apparent by referring to the drawings and embodiments described in detail below. However, the disclosure is not limited to the embodiments disclosed hereinafter and may be realized in various forms.

Hereinafter, embodiments of the disclosure will be described in detail by referring to the accompanying drawings. In descriptions with reference to the drawings, the same reference numerals are given to elements that are the same or substantially the same and descriptions will not be repeated.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. That is, the expression “A and/or B” may indicate A, B, or A and B. Throughout the disclosure, the expression “at least one of a, b or c”, “at least one of a, b and c” or “at least one selected from a, b and c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or element is referred to as being formed “on” another layer, area, or element, it can be directly or indirectly formed on the other layer, region, or element. That is, for example, intervening layers, regions, or elements may be present.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

When a certain embodiment may be implemented differently, a specific process order may be performed differently from the described order. For example, two consecutively described processes may be performed substantially at the same time or performed in an order opposite to the described order.

In embodiments hereinafter, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

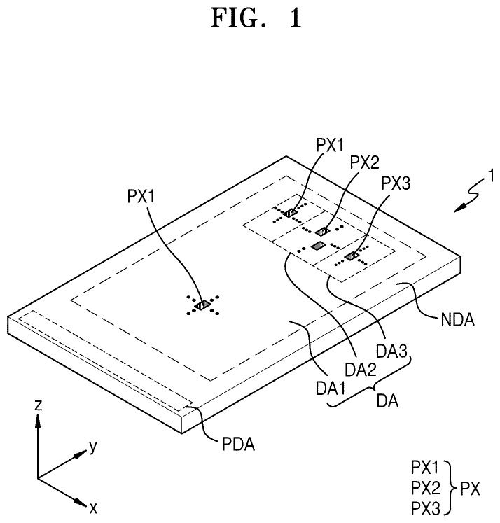

FIG. 1 is a schematic plan view of a display apparatus 1 according to an embodiment.

Referring to FIG. 1, an embodiment of the display apparatus 1 may include a display area DA and a non-display area NDA outside or adjacent to the display area DA. The display area DA may include a first display area DA1, a second display area DA2, and a third display area DA3. A sub-pixel PX may be arranged in the first display area DA1, the second display area DA2, and the third display area DA3, and a sub-pixel PX may not be arranged in the non-display area NDA. The display apparatus 1 may provide an image to the outside by using light emitted from the sub-pixel PX arranged in the display area DA. The non-display area NDA may include a pad area PDA arranged on at least a side thereof.

The non-display area NDA may at least partially surround the first display area DA1. In an embodiment, for example, the non-display area NDA may entirely surround the first display area DA1. In the non-display area NDA, a driver, etc. for providing an electrical signal or a power supply to the first display area DA1 may be arranged. In the non-display area NDA, the pad area PDA, to which an electronic element, a printed circuit board, etc. may be electrically connected, may be arranged.

The sub-pixel PX may be defined as an area in which light is emitted by a display element. Each of a plurality of sub-pixels PX may emit light, for example, red, green, blue, or white light. Each sub-pixel PX may be, for example, a red sub-pixel, a green sub-pixel, or a blue sub-pixel. According to an embodiment, the display apparatus 1 may include a first sub-pixel PX1, a second sub-pixel PX2, and a third sub-pixel PX3.

The first display area DA1 may at least partially surround the second display area DA2 and the third display area DA3. According to an embodiment, the first display area DA1 may only partially surround the second display area DA2 and the third display area DA3. According to an alternative embodiment, the first display area DA1 may entirely surround the second display area DA2 and the third display area DA3. The first display area DA1 may include the first sub-pixel PX1. The first sub-pixel PX1 may be provided in plural in the first display area DA1.

The third display area DA3 may be adjacent to the second display area DA2. The third display area DA3 may be arranged at a side of the second display area DA2. In an embodiment, for example, the second display area DA2 and the third display area DA3 may be arranged in parallel with each other in a first direction (for example, an x direction or a −x direction). In an alternative embodiment, for example, the second display area DA2 and the third display area DA3 may be arranged in parallel with each other in a second direction (for example, a y direction or a −y direction). The third display area DA3 may be omitted.

At least one of the second display area DA2 and the third display area DA3 may have various shapes, such as a circular shape, an oval shape, a polygonal shape such as a quadrangular shape, a star shape, a diamond shape, etc., in a plan view (for example, an x-y plane). In an embodiment, for example, as illustrated in FIG. 1, each of the second display area DA2 and the third display area DA3 may have a quadrangular shape.

FIG. 1 illustrates an embodiment where the second display area DA2 and the third display area DA3 may be arranged at an upper (a +y direction) middle side of the first display area DA1 having approximately a quadrangular shape when viewed in a direction (for example, a z direction) approximately perpendicular to an upper surface of the display apparatus 1 or a thickness direction of the display apparatus. However, the disclosure is not limited thereto. Alternatively, the second display area DA2 and the third display area DA3 may be arranged, for example, at an upper right side or an upper left side of the first display area DA1.

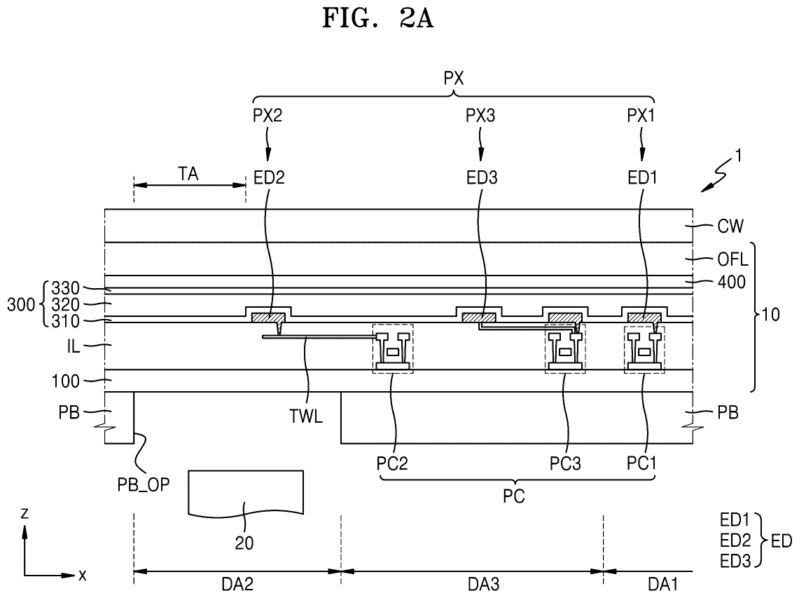

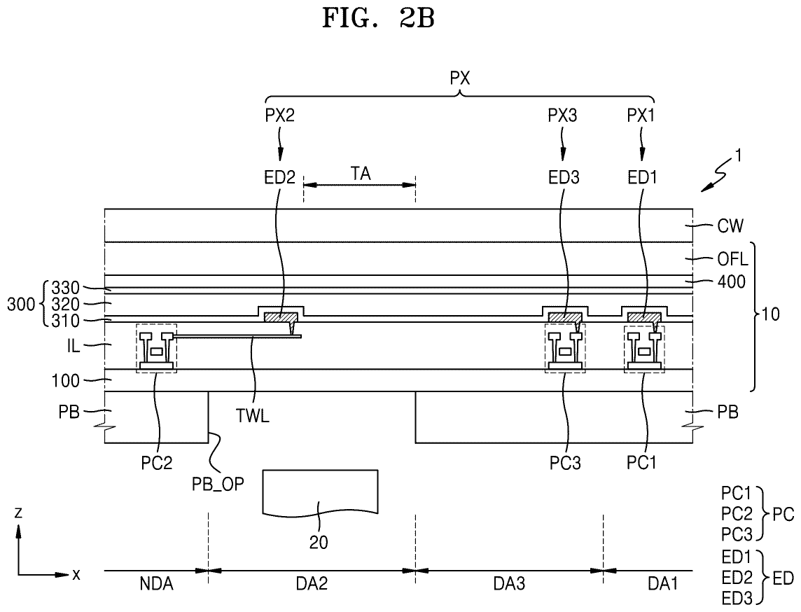

At least one of the second display area DA2 and the third display area DA3 may include a transmission area TA (see FIG. 2A) through which light or/and sound is transmitted. Also, at least one of the second display area DA2 and the third display area DA3 may be where the sub-pixel PX may be arranged. The second sub-pixel PX2 may be arranged in the second display area DA2. The second sub-pixel PX2 may be provided in plural in the second display area DA2. The third sub-pixel PX3 may be arranged in the third display area DA3. The third sub-pixel PX3 may be provided in plural in the third display area DA3.

According to an embodiment, an image displayed in at least one of the second display area DA2 and the third display area DA3 may have a lower resolution than an image displayed in the first display area DA1. In an embodiment, for example, a resolution of the second display area DA2 may be about ½, ⅜, ⅓, ¼, 2/9, ⅛, 1/9, 1/16, etc. of a resolution of the first display area DA1. In an embodiment, for example, the resolution of the first display area DA1 may be about 400 pixels per inch (ppi) or higher, and the resolution of the second display area DA2 may be about 200 ppi or about 100 ppi. According to an embodiment, a resolution of at least one of the second display area DA2 and the third display area DA3 may be the same as a resolution of the first display area DA1.

In an embodiment where the sub-pixel PX is not arranged in the transmission area TA, the number of sub-pixels PX which may be arranged per unit area in at least one of the second display area DA2 and the third display area DA3 may be less than the number of sub-pixels PX which may be arranged per unit area in the first display area DA1. In an embodiment, for example, the number of second sub-pixels PX2 which may be arranged per unit area in the second display area DA2 may be less than the number of first sub-pixels PX1 which may be arranged per unit area in the first display area DA1.

At least one of the second display area DA2 and the third display area DA3 may have a high transmittance with respect to light or sound. In an embodiment, for example, a transmittance of at least one of the second display area DA2 and the third display area DA3 may be about 10% or higher or more desirably, about 40% or higher, about 25% or higher, about 50% or higher, about 85% or higher, or about 90% or higher.

Hereinafter, for convenience of description, embodiments in which the display apparatus 1 is a smartphone will be described. However, the display apparatus 1 according to the disclosure is not limited thereto. The display apparatus 1 may include various products, such as a television, a notebook computer, a monitor, an advertising board, an Internet of things (IOT) device, etc., as well as portable electronic devices, such as a mobile phone, a smartphone, a tablet personal computer (PC), a mobile communication terminal, an electronic notebook, an electronic book, a portable multimedia player (PMP), a navigation device, an ultra mobile PC (UMPC), etc. Also, the display apparatus 1 according to an embodiment may be used in wearable devices, such as a smart watch, a watch phone, a glasses-type display, and a head-mounted display (HMD). Also, the display apparatus 1 according to an embodiment may be used as: a center information display (CID) on a gauge of a vehicle or a center fascia or a dashboard of the vehicle; a room mirror display substituting a side-view mirror of a vehicle; or a display screen disposed on a rear surface of a front seat, as an entertainment device for a backseat of a vehicle.

FIGS. 2A and 2B are schematic cross-sectional views of the display apparatus 1 according to an embodiment.

Referring to FIGS. 2A and 2B, an embodiment of the display apparatus 1 may include a display panel 10 and a component 20 arranged on a rear surface (a bottom surface) of the display panel 10. The display panel 10 may include a substrate 100, a display portion, an encapsulation layer 300, a touch sensor layer 400, an optical functional layer OFL, a cover window CW, and a panel protection member PB arranged on a rear surface of the substrate 100. The display portion may include an insulating layer IL, a sub-pixel circuit PC, and a display element.

The display panel 10 may include the first display area DA1, the second display area DA2, and the third display area DA3. In other words, the first display area DA1, the second display area DA2, and the third display area DA3 may be defined on the substrate 100 and multiple layers on the substrate 100. Hereinafter, embodiments where the substrate 100 includes the first display area DA1, the second display area DA2, and the third display area DA3 will be described in detail.

The substrate 100 may include an insulating material, such as glass, quartz, and polymer resins. The substrate 100 may include a rigid substrate or a flexible substrate that is bendable, foldable, rollable, etc.

The insulating layer IL and the sub-pixel circuit PC may be arranged on the substrate 100. The insulating layer IL may insulate the elements of the display panel 10 from each other. The insulating layer IL may include at least one selected from an organic material and an inorganic material.

The sub-pixel circuit PC may be electrically connected to the display element and may be configured to drive the display element. The sub-pixel circuit PC may be arranged in the insulating layer IL. According to an embodiment, the sub-pixel circuit PC may include a first sub-pixel circuit PC1, a second sub-pixel circuit PC2, and a third sub-pixel circuit PC3. The first sub-pixel circuit PC1 may be arranged in the first display area DA1. The second sub-pixel circuit PC2 and the third sub-pixel circuit PC3 may be arranged in the third display area DA3. According to an embodiment, the sub-pixel circuit PC may not be arranged in the second display area DA2. In such an embodiment, a transmittance (for example, a light transmittance) of the display panel 10 in the second display area DA2 may be relatively higher than a transmittance of the display panel 10 in the first display area DA1 and the third display area DA3.

The display element may be arranged on the insulating layer IL. According to an embodiment, the display element may include an organic light-emitting diode including an organic emission layer. However, the disclosure is not limited thereto. According to an alternative embodiment, the display element may include a light-emitting diode including an inorganic material or a quantum-dot light-emitting diode including quantum dots. In an embodiment, for example, an emission layer of the display element may include an organic material, an inorganic material, quantum dots, an organic material and quantum dots, or an inorganic material and quantum dots. Hereinafter, for convenience of description, embodiments where the display element includes an organic light-emitting diode will be described in detail.

The display panel 10 may include a plurality of display elements e.g., first display elements ED1, second display elements ED2 and third display elements ED3. The plurality of display elements may be arranged in the first display area DA1, the second display area DA2, and the third display area DA3. According to an embodiment, the display element may emit light to realize a sub-pixel PX. In an embodiment, for example, the first display elements ED1 arranged in the first display area DA1 may emit light to realize the first sub-pixels PX1. The second display elements ED2 arranged in the second display area DA2 may emit light to realize the second sub-pixels PX2. The third display elements ED3 arranged in the third display area DA3 may emit light to realize the third sub-pixels PX3.

According to an embodiment, as illustrated in FIG. 2A, the second sub-pixel circuit PC2 configured to drive the second display element ED2 may not be arranged in the second display area DA2 and may be arranged in the third display area DA3 between the first display area DA1 and the second display area DA2. According to an alternative embodiment, as illustrated in FIG. 2B, the second sub-pixel circuit PC2 configured to drive the second display element ED2 may not be arranged in the third display area DA3 and may be arranged in the non-display area NDA. In such an embodiment, the second sub-pixel circuit PC2 may be arranged not to overlap the second display element ED2.

According to an embodiment, the second sub-pixel circuit PC2 arranged in the third display area DA3 and the second display element ED2 arranged in the second display area DA2 may be electrically connected to each other through a connection line TWL. In such an embodiment, the connection line TWL may extend from the third display area DA3 to the second display area DA2. The connection line TWL may be arranged in the second display area DA2 and the third display area DA3. According to an alternative embodiment, as illustrated in FIG. 2B, the second sub-pixel circuit PC2 arranged in the non-display area NDA and the second display element ED2 arranged in the second display area DA2 may be electrically connected to each other through a connection line TWL. The connection line TWL may extend from the non-display area NDA to the second display area DA2. The connection line TWL may be arranged in the second display area DA2 and the non-display area NDA.

The transmission area TA may be defined as where the second sub-pixel PX is not arranged in the second display area DA2. The transmission area TA may be an area through which light/a signal emitted from or incident into the component 20 arranged to correspond to the second display area DA2 may be transmitted. The connection line TWL connecting the second sub-pixel circuit PC2 with the second display element ED2 may be arranged in the transmission area TA. The connection line TWL may include a transparent conductive material having a high transmittance, and thus, in such an embodiment where the connection line TWL is arranged in the transmission area TA, the transmittance of the transmission area TA may be secured.

An encapsulation member may cover the display element. The encapsulation member may include the encapsulation layer 300 or a sealing substrate. According to an embodiment, the encapsulation member may include the encapsulation layer 300 including at least one inorganic encapsulation layer and at least one organic encapsulation layer. In an embodiment, for example, the encapsulation layer 300 may include a first inorganic encapsulation layer 310, a second inorganic encapsulation layer 330, and an organic encapsulation layer 320 therebetween.

The touch sensor layer 400 may obtain coordinate information according to an external input, for example, a touch event. The touch sensor layer 400 may include a touch electrode and touch lines connected to the touch electrode. The touch sensor layer 400 may sense the external input based on a magnetic capacitance method or a mutual capacitance method.

The touch sensor layer 400 may be arranged on the encapsulation layer 300. In an embodiment, for example, the touch sensor layer 400 may be separately formed on a touch substrate and then may be coupled onto the encapsulation layer 300 through an adhesive layer, such as an optical clear adhesive (OCA). According to an alternative embodiment, the touch sensor layer 400 may be formed directly above the encapsulation layer 300, and in such an embodiment, the adhesive layer may not be arranged between the touch sensor layer 400 and the encapsulation layer 300.

The optical functional layer OFL may include a reflection prevention layer. The reflection prevention layer may reduce the reflectivity of light (external light) that is incident toward the display panel 10 from the outside. According to an embodiment, the optical functional layer OFL may include a polarization film. Alternatively, the optical functional layer OFL may include a filter plate including a black matrix and color filters.

The cover window CW may be arranged on the display panel 10. The cover window CW may protect the display panel 10. The cover window CW may include at least one selected from glass, sapphire, and plastic. The cover window CW may include, for example, ultra-thin glass (UTG) or colorless polyimide (CPI).

The panel protection member PB may be arranged below the substrate 100. The panel protection member PB may support and protect the substrate 100. According to an embodiment, an opening PB_OP overlapping the second display area DA2 may be defined in the panel protection member PB. According to some embodiments, the opening PB_OP of the panel protection member PB may overlap the second display area DA2 and the third display area DA3. The panel protection member PB may include polyethylene terephthalate or polyimide.

The component 20 may be arranged below the display panel 10. According to an embodiment, the component 20 may be arranged on the opposite side to the cover window CW with the display panel 10 therebetween. According to an embodiment, the component 20 may overlap the second display area DA2. According to an embodiment, the component 20 may overlap the second display area DA2 and the third display area DA3.

The component 20 may include a camera using infrared rays or visible rays and may include a capturing device. Alternatively, the component 20 may include a solar battery, a flash device, an illuminance sensor, a proximity sensor, an iris sensor, etc. Alternatively, the component 20 may have a function to receive sound. To minimize limiting of the function of the component 20, the second sub-pixel circuit PC2 may not be arranged in the second display area DA2 below which the component 20 is arranged. That is, the second sub-pixel circuit PC2 configured to drive the second display element ED2 arranged in the second display area DA2 may not be arranged in the second display area DA2 and may be arranged in the third display area DA3. Thus, the transmittance (for example, the light transmittance) of the display panel 10 in the second display area DA2 may be higher than the transmittance (for example, the light transmittance) of the display panel 10 in the third display area DA3.

According to an embodiment, the component 20 may be an infrared (IR) sensor for transmitting/receiving IR rays. In such an embodiment, the IR rays generated by the component 20 or existing due to the component 20 may affect operations of transistors included in a pixel circuit.

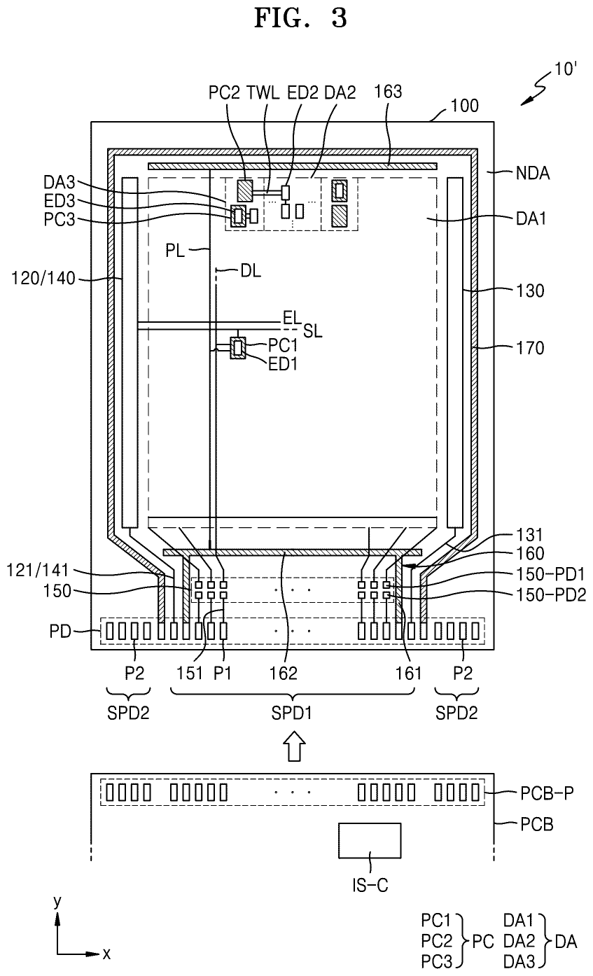

FIG. 3 is a schematic plan view of a display panel 10′ according to an embodiment.

Referring to FIG. 3, in an embodiment, the substrate 100 of the display panel 10′ may include a display area DA and a non-display area NDA. The display area DA may include a first display area DA1, a second display area DA2, and a third display area DA3.

The display panel 10′ may include a plurality of sub-pixels PX arranged in the display area DA, for example, the first display area DA1, the second display area DA2, and the third display area DA3. A light-emitting diode of each sub-pixel PX may emit, for example, red, green, blue, or white light.

Each of sub-pixel circuits PC configured to drive the sub-pixels PX in the display area DA may be connected to a signal line or a voltage line configured to control on/off, brightness, etc. of the display element. In an embodiment, for example, as illustrated in FIG. 3 the display panel 10′ may include signal lines, such as a scan line SL extending in a first direction (for example, an x direction) and a data line DL extending in a second direction (for example, a y direction), and a voltage line, such as a driving voltage line PL.

The first display element ED1 corresponding to the first sub-pixel PX1 (FIG. 2A) may be arranged in the first display area DA1. The first sub-pixel circuit PC1 connected to the first display element ED1 may be arranged in the first display area DA1 and may overlap the first display element ED1.

The second display element ED2 corresponding to the second sub-pixel PX2 (FIG. 2A) may be arranged in the second display area DA2. Referring to FIG. 3, the second display element ED2 may be arranged in the second display area DA2, and the second sub-pixel circuit PC2 may be arranged in the third display area DA3. The second display element ED2 may be connected to the second sub-pixel circuit PC2 through a connection line TWL. According to an alternative embodiment, the second display element ED2 may be arranged in the second display area DA2, and the second sub-pixel circuit PC2 may be arranged in the non-display area NDA.

The third display element ED3 corresponding to the third sub-pixel PX3 (FIG. 2A) may be arranged in the third display area DA3. The third sub-pixel circuit PC3 connected to the third display element ED3 may be arranged in the third display area DA3.

Each of the first to third sub-pixel circuits PC1 to PC3 may be electrically connected to outer circuits arranged in the non-display area NDA. A first scan driving circuit 120, a second scan driving circuit 130, an emission control driving circuit 140, a first power supply line 160, and a second power supply line 170 may be arranged in the non-display area NDA.

The first scan driving circuit 120 and the second scan driving circuit 130 may be configured to provide a scan signal to each sub-pixel PX through the scan line SL. The second scan driving circuit 130 may be arranged in parallel with the first scan driving circuit 120 with the display area DA therebetween. Some of the sub-pixels PX arranged in the display area DA may be electrically connected to the first scan driving circuit 120, and the others may be electrically connected to the second scan driving circuit 130. According to an alternative embodiment, the second scan driving circuit 130 may be omitted.

The emission control driving circuit 140 may be arranged at a side of the display area DA. The emission control driving circuit 140 may be configured to provide an emission control signal to each sub-pixel PX through an emission control line EL.

A pad portion PD may be arranged at a side of the substrate 100. The pad portion PD may include a plurality of pads P. The plurality of pads P may not be covered by an insulating layer and may be exposed and may be electrically connected to a printed circuit board PCB. A pad portion PCB-P of the printed circuit board PCB may be electrically connected to the pad portion PD of the display panel 10′. The printed circuit board PCB may include a rigid circuit board or a flexible circuit board. The printed circuit board PCB may be directly coupled to the display panel 10′ or may be connected to the display panel 10′ through another circuit board.

According to an embodiment, a data driving circuit 150 configured to control an operation of the display panel 10′ may be arranged on the printed circuit board PCB. In such an embodiment, an input sensing circuit IS-C configured to control the touch sensor layer 400 may be arranged on the printed circuit board PCB. According to an embodiment, as illustrated in FIG. 3, the data driving circuit 150 and the input sensing circuit IS-C may be mounted on the printed circuit board PCB as a single integrated chip. The printed circuit board PCB may include the circuit board pad portion PCB-P which is electrically connected to the display panel 10′. Although not shown, the printed circuit substrate PCB may further include signal lines configured to connect the circuit board pad portion PCB-P of the printed circuit board PCB with the data driving circuit 150 and/or the input sensing circuit IS-C.

The first power supply line 160 may include a first sub-line 162 and a second sub-line 163 extending in parallel with each other in the first direction (for example, the x direction) with the display area DA therebetween and may be configured to supply a first power voltage (for example, a driving voltage or an ELVDD) through a power transmission line 161 extending in the second direction (for example, the y direction). The first power voltage may be provided to the sub-pixel circuit PC of each sub-pixel PX through the driving voltage line PL connected to the first power supply line 160. The second power supply line 170 partially surrounding the display area DA may be arranged in the non-display area NDA. In an embodiment, for example, the second power supply line 170 may have a loop shape that is open toward the pad portion PD. A second power voltage (for example, a common voltage or an ELVSS) may be transmitted to the second power supply line 170, and the second power voltage may be provided to an opposite electrode of each sub-pixel PX connected to the second power supply line 170.

The pad portion PD may be arranged in the pad area PDA (FIG. 1) of the non-display area NDA. The pad portion PD may include pads P1 and P2 continually arranged by being spaced apart from each other by a predetermined distance. The pad portion PD may include a first sub-pad portion SPD1. The first sub-pad portion SPD1 may include a plurality of first pads P1 configured to transmit an electrical signal to the sub-pixel circuit PC. The plurality of first pads P1 may be connected to an end of a signal transmission line 151, which is the data line DL extending to the non-display area NDA. Some of the plurality of first pads P1 may be connected to ends of signal transmission lines 121, 131, and 141 and the power transmission line 161, where the signal transmission lines 121, 131, and 141 are connected to the driving circuits 120, 130, and 140, and the power transmission line 161 is connected to the first power supply line 160.

The pad portion PD may further include a second sub-pad portion SPD2 arranged at both sides of the first sub-pad portion SPD1. The second sub-pad portion SPD2 may include a plurality of second pads P2 configured to transmit an electrical signal to the touch sensor layer 400. According to an embodiment, the plurality of second pads P2 may be selectively provided in a case where the touch sensor layer 400 is directly provided on the encapsulation layer 300, or may be omitted in a case where the touch sensor layer is provided as a separate panel and coupled to the encapsulation layer 300. The plurality of second pads P2 may be provided as floating electrodes and may be electrically insulated from signal lines connected to the sub-pixel PX. The plurality of second pads P2 may overlap a pad portion included in the touch sensor layer 400.

According to an embodiment, the data driving circuit 150 may be directly arranged on the substrate 100. The data driving circuit 150 may be provided in the form of a chip, and first chip pads 150-PD1 and second chip pads 150-PD2 may be provided where the data driving circuit 150 is to be mounted. Each of the first chip pads 150-PD1 may be connected to the data line DL, and the second chip pads 150-PD2 may be connected to the plurality of first pads P1 through the signal transmission lines 151. The data driving circuit 150 may be connected to the first chip pads 150-PD1 and the second chip pads 150-PD2. Accordingly, the data line DL may be electrically connected to the pad portion DP through the data driving circuit 150 provided as a control circuit chip.

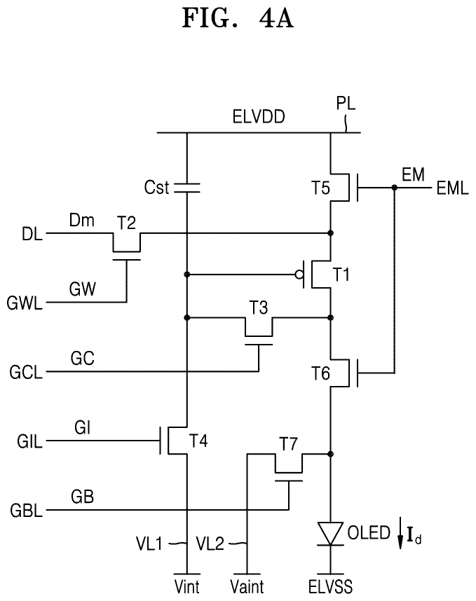

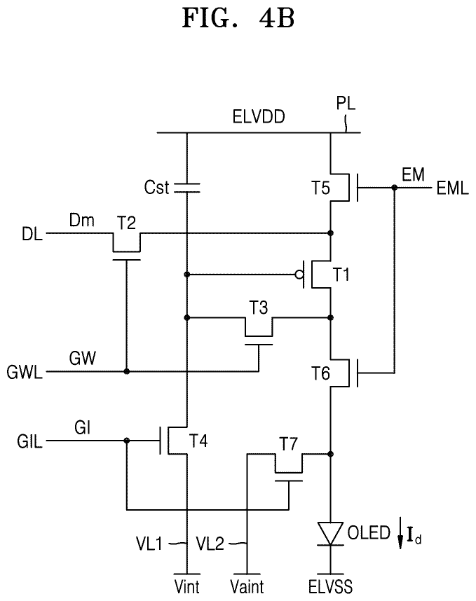

FIGS. 4A and 4B are schematic equivalent circuit diagrams of a light-emitting diode and a sub-pixel circuit which are arranged in a display panel according to an embodiment. The sub-pixel circuit illustrated in FIGS. 4A and 4B may correspond to each of the first sub-pixel circuit PC1, the second sub-pixel circuit PC2, and the third sub-pixel circuit PC3 described above with reference to FIG. 3. An organic light-emitting diode OLED illustrated in FIGS. 4A and 4B may correspond to each of the first display element ED1, the second display element ED2, and the third display element ED3 described above with reference to FIG. 3.

Referring to FIGS. 4A and 4B, one sub-pixel PX may include the sub-pixel circuit and a display element electrically connected to the sub-pixel circuit. The display element may include an organic light-emitting diode OLED having an anode (or a pixel electrode) and a cathode (or an opposite electrode).

In an embodiment, for example, the sub-pixel circuit may include first to seventh transistors T1 to T7 and a capacitor Cst as illustrated in FIG. 4A. The first to seventh transistors T1 to T7 and the capacitor Cst may be connected to first to fourth scan lines GWL, GCL, GIL, and GBL configured to transmit first to fourth scan signals GW, GC, GI, and GB, respectively, a data line DL configured to transmit a data signal Dm, an emission control line EML configured to transmit an emission control signal EM, a driving voltage line PL configured to transmit a first power voltage ELVDD, a first initialization voltage line VL1 configured to transmit a first initialization voltage Vint, a second initialization voltage line VL2 configured to transmit a second initialization voltage Vaint, and a common electrode to which a second power voltage ELVSS is applied.

The first transistor T1 may be a driving transistor, a magnitude of a drain current of which is determined based on a gate-source voltage, and the second to seventh transistors T2 to T7 may be switching transistors, which are turned on/off in response to the gate-source voltage, in reality, a gate voltage. The first to seventh transistors T1 to T7 may include thin-film transistors. Some of the first to seventh transistors T1 to T7 may be provided as n-channel metal-oxide semiconductor field-effect transistors (n-channel MOSFETs) (NMOS transistors), and the others of the first to seventh transistors T1 to T7 may be provided as p-channel metal-oxide semiconductor field-effect transistors (p-channel MOSFETs) (PMOS transistors). In an embodiment, for example, as illustrated in FIG. 4A, the first transistor T1 of the first to seventh transistors T1 to T7 may be provided as a PMOS transistor, and the second to seventh transistors T2 to T7 may be provided as NMOS transistors.

The capacitor Cst may be connected between the driving voltage line PL and a gate of the first transistor T1. The capacitor Cst may have a lower electrode connected to the gate of the first transistor T1 and an upper electrode connected to the driving voltage line PL.

A first gate electrode of the first transistor T1 may be connected to the capacitor Cst. One of a source area and a drain area of the first transistor T1 may be connected to the driving voltage line PL through the fifth transistor T5, and the other of the source area and the drain area of the first transistor T1 may be electrically connected to a sub-pixel electrode of the organic light-emitting diode OLED through the sixth transistor T6. The first transistor T1 may be configured to receive a data signal Dm according to a switching operation of the second transistor T2 and supply a driving current Id to the organic light-emitting diode OLED.

A second gate electrode of the second transistor T2 may be connected to the first scan line GWL configured to transmit the first scan signal GW. One of a source area and a drain area of the second transistor T2 may be connected to the data line DL, and the other of the source area and the drain area of the second transistor T2 may be connected to the first transistor T1 and connected to the driving voltage line PL through the fifth transistor T5. The switching transistor T2 may be turned on in response to the first scan signal GW received through the first scan line GWL and may be configured to perform a switching operation of transmitting the data signal Dm transmitted through the data line DL to the first transistor T1.

A third gate electrode of the third transistor T3 may be connected to the second scan line GCL. One of a source area and a drain area of the third transistor T3 may be connected to the anode of the organic light-emitting diode OLED through the sixth transistor T6. The other of the source area and the drain area of the third transistor T3 may be connected to the capacitor Cst and the first gate electrode of the first transistor T1. The third transistor T3 may be turned on in response to the second scan signal GC received through the second scan line SL2 and may diode-connect the first transistor T1.

A fourth gate electrode of the fourth transistor T4 may be connected to the third scan line GIL. One of a source area and a drain area of the fourth transistor T4 may be connected to the first initialization voltage line VL1. The other of the source area and the drain area of the fourth transistor T4 may be connected to a lower electrode of the capacitor Cst and the first gate electrode of the first transistor T1. The fourth transistor T4 may be turned on in response to the third scan signal GI received through the third scan line GIL and may be configured to perform an initialization operation of initializing a voltage of the first gate electrode of the first transistor T1 by transmitting the first initialization voltage Vint to the first gate electrode of the first transistor T1.

A fifth gate electrode of the fifth transistor T5 may be connected to the emission control line EML, one of a source area and a drain area of the fifth transistor T5 may be connected to the driving voltage line PL, and the other of the source area and the drain area of the fifth transistor T5 may be connected to the first transistor T1 and the second transistor T2.

A sixth gate electrode of the sixth transistor T6 may be connected to the emission control line EL, one of a source area and a drain area of the sixth transistor T6 may be connected to the first transistor T1 and the third transistor T3, and the other of the source area and the drain area of the sixth transistor T6 may be electrically connected to the anode of the organic light-emitting diode OLED.

The fifth transistor T5 and the sixth transistor T6 may be simultaneously turned on in response to the emission control signal EM received through the emission control line EL so that the first power voltage ELVDD may be transmitted to the organic light-emitting diode OLED, and a driving current la may flow in the organic light-emitting diode OLED.

A seventh gate electrode of the seventh transistor T7 may be connected to the fourth scan line GBL, one of a source area and a drain area of the seventh transistor T7 may be connected to the anode of the organic light-emitting diode OLED, and the other of the source area and the drain area of the seventh transistor T7 may be connected to the second initialization voltage line VL2 to receive the second initialization voltage Vaint. The seventh transistor T7 may be turned on in response to the fourth scan signal GB received through the fourth scan line GBL and may be configured to initialize the anode of the organic light-emitting diode OLED. In an embodiment, as shown in FIG. 4B, the fourth scan line GBL may be the same as the third scan line GIL. In an embodiment, the corresponding scan line may be configured to transmit a same electrical signal based on a time interval to function as the third scan line GIL and also the fourth scan line GBL. According to some embodiments, the seventh transistor T7 may be omitted.

The capacitor Cst may be connected to the driving voltage line PL and the first gate electrode of the first transistor T1 and may be configured to store and retain a voltage corresponding to a difference between voltages of the driving voltage line PL and the first gate electrode of the first transistor T1 to retain a voltage applied to the first gate electrode of the first transistor T1.

The sub-pixel circuit PC is not limited to the number of transistors and the number of capacitors and the circuit design described with reference to FIGS. 4A and 4B and may be variously changed or modified.

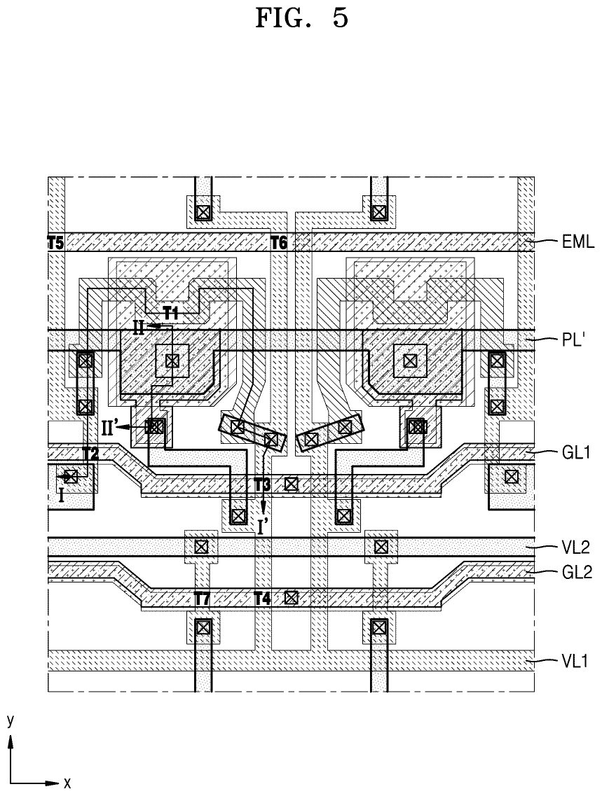

FIG. 5 is a schematic plan view showing locations of transistors and a storage capacitor of a pixel included in a display apparatus according to an embodiment.

Referring to FIG. 5, each sub-pixel circuit may include transistors and capacitors. In an embodiment, for example, each sub-pixel circuit may include a first transistor T1 as a driving transistor, a second transistor T2 as a switching transistor, a third transistor T3 as a compensation transistor, a fourth transistor T4 as a first initialization transistor, a fifth transistor T5 as an operation control transistor, a sixth transistor T6 as an emission control transistor, a seventh transistor T7 as a second initialization transistor, and a capacitor Cst. According to an embodiment, the first transistor T1 may be provided as a thin-film transistor including a silicon semiconductor, and the second to seventh transistors T2 to T7 may be provided as thin-film transistors including oxide semiconductors.

Each sub-pixel circuit may be connected to a plurality of signal lines, a sub-voltage line PL′, a first initialization voltage line VL1, and a second initialization voltage line VL2 extending in a first direction (for example, an x direction) or a second direction (for example, a y direction) crossing the first direction. The signal lines may include a data line DL, an emission control line EL, a first scan line GWL, and a third scan line GIL. At least one selected from the signal lines, the first and second initialization voltage lines VL1 and VL2, and the sub-voltage line PL′ may be shared by neighboring sub-pixels.

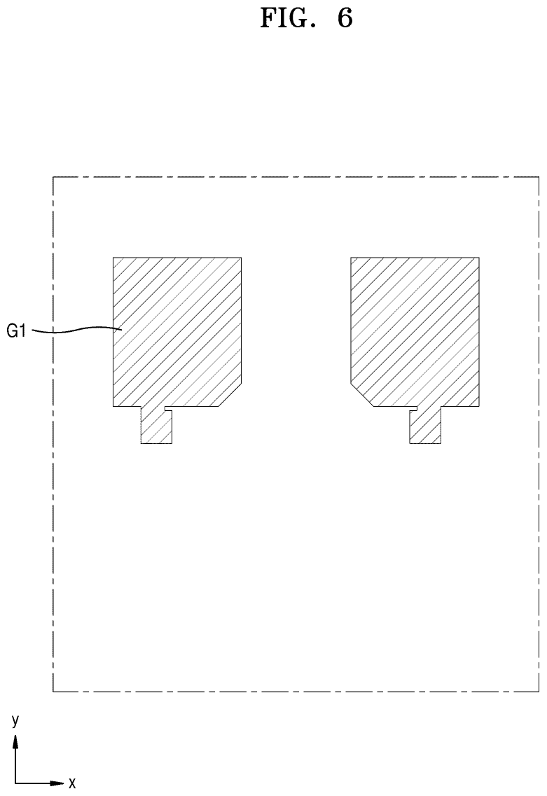

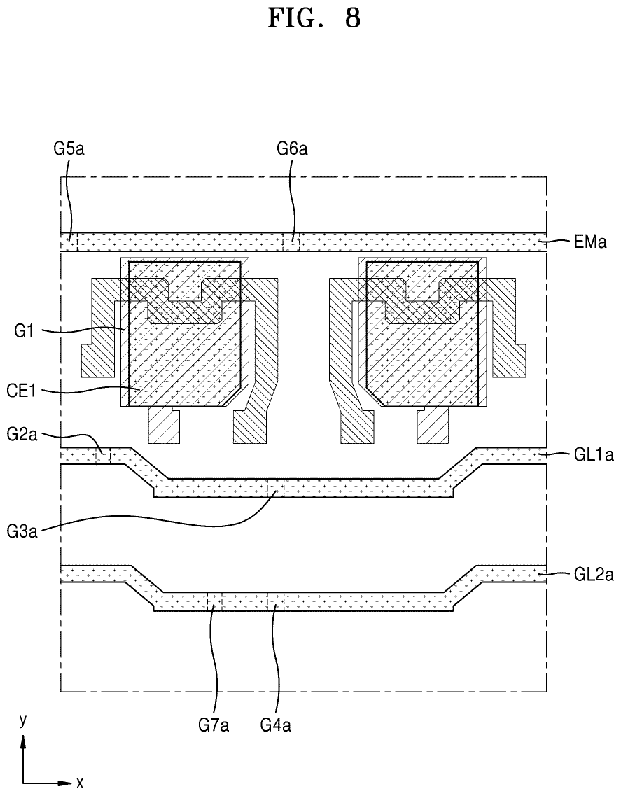

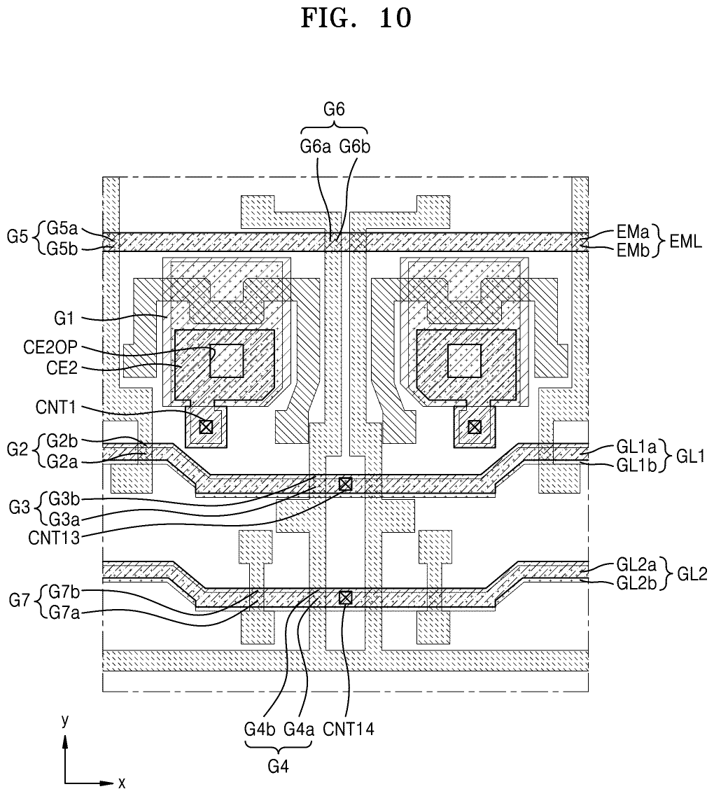

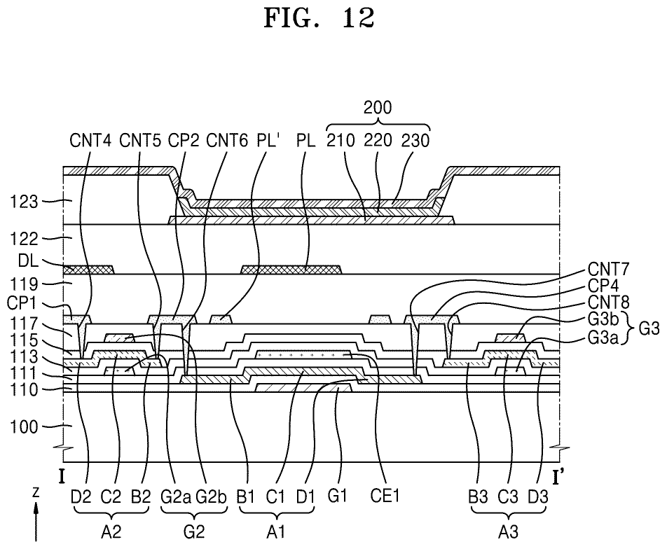

FIGS. 6 to 11 are schematic plan views showing a process of forming elements of the display apparatus illustrated in FIG. 5. FIG. 12 is a schematic cross-sectional view of the display apparatus taken along line I-I′ of FIG. 5.

Referring to FIGS. 5 to 12, the substrate 100 may include a glass material, a ceramic material, a metal material, a plastic material, or a material having a flexible or bendable property. In an embodiment where the substrate 100 has a flexible or bendable property, the substrate 100 may include polymer resins, such as polyethersulphone (PES), polyacrylate, polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP).

The substrate 100 may have a single-layered or a multi-layered structure, each layer therein including at least one selected from the materials described above. In an embodiment, where the substrate 100 has a multi-layered structure, the substrate 100 may further include an inorganic layer. In an embodiment, for example, the substrate 100 may include a first organic base layer, a first inorganic barrier layer, a second organic base layer, and a second inorganic barrier layer. Each of the first organic base layer and the second organic base layer may include a polymer resin. The first inorganic barrier layer and the second inorganic barrier layer may be barrier layers for preventing the penetration of external foreign materials and may include a single layer or multiple layers including an inorganic insulating material such as silicon nitride and/or silicon oxide.

A bottom metal layer may be arranged on the substrate 100. The bottom metal layer may include at least one material selected from Al, Pt, Pd, Ag, Mg, Au, Ni, Nd, Ir, Cr, Li, Ca, Mo, Ti, W, and Cu. According to some embodiments, the bottom metal layer may have a single layer including Mo, a double-layered structure in which a Mo layer and a Ti layer are stacked, or a triple-layered structure in which a Ti layer, an Al layer, and a Ti layer are stacked.

The bottom metal layer may include a first gate electrode G1 of the first transistor T1. The first gate electrode G1 may have an isolated shape in a plan view and may be formed to entirely overlap or cover a first channel area C1 of a first semiconductor layer A1 described below.

A buffer layer 110 may be arranged on the bottom metal layer. The buffer layer 110 may include an inorganic insulating layer including an inorganic insulating material such as silicon nitride and/or silicon oxide, and may have a single layer or a layered structure, each layer therein including at least one selected from the material described above.

A silicon semiconductor pattern may be arranged on the buffer layer 110. The silicon semiconductor pattern may include a silicon-based material, for example, polycrystalline silicon. The silicon semiconductor pattern may include the first semiconductor layer A1. The first semiconductor layer A1 may include a first channel area C1 and a first area and a second area B1 and D1 arranged at both sides of the first channel area C1. The first and second areas B1 and D1 of the first semiconductor layer A1 may be doped with impurities and may have a higher electrical conductivity than the first channel area C1. One of the first and second areas B1 and D1 may be a source area, and the other thereof may be a drain area. The first channel area C1 may have a curved shape (for example, a curved omega shape) in a plan view, such that the first channel area C1 may have an increased length in a narrow space.

The first semiconductor layer A1 may overlap the bottom metal layer. In an embodiment, for example, the first channel area C1 of the first semiconductor layer A1 may overlap the bottom metal layer in the z direction or in a thickness direction of the substrate 100. According to an embodiment, a portion of the bottom metal layer, e.g., the portion overlapping the first channel area C1, may be the first gate electrode G1.

A first gate insulating layer 111 may be arranged on the silicon semiconductor pattern including the first semiconductor layer A1. The first gate insulating layer 111 may include an inorganic insulating layer including an inorganic insulating material such as silicon oxide, silicon nitride, and/or silicon oxynitride and may have a single-layered or a multi-layered structure, each layer therein including at least one selected from the material described above.

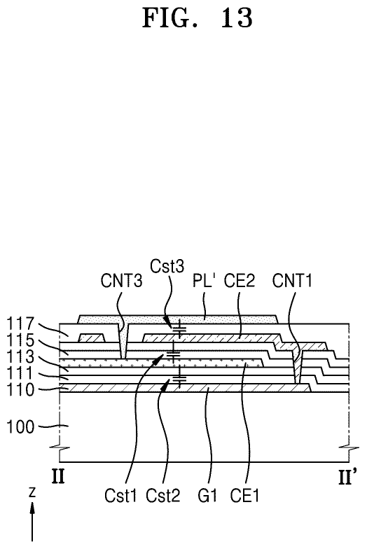

A first electrode CE1, a lower emission control line EMa, a first lower gate line GL1a, and a second lower gate line GL2a may be arranged on the first gate insulating layer 111. The first electrode CE1 may be a lower electrode of the capacitor Cst. The first electrode CE1 and the first gate electrode G1 may collectively define or be included in a second capacitor Cst2 (see FIG. 13).

The first electrode CE1, the lower emission control line EMa, the first lower gate line GL1a, and the second lower gate line GL2a may include Al, Pt, Pd, Ag, Mg, Au, Ni, Nd, Ir, Cr, Li, Ca, Mo, Ti, W, and/or Cu and may include a single layer or multiple layers, each layers therein including at least one selected from the material described above.

The lower emission control line EMa may include a fifth lower gate electrode G5a and a sixth lower gate electrode G6a. The first lower gate line GL1a may include a second lower gate electrode G2a and a third lower gate electrode G3a. The second lower gate line GL2a may include a seventh lower gate electrode G7a and a fourth lower gate electrode G4a. Each of the lower emission control line ELa, the first lower gate line GL1a, and the second lower gate line GL2a may extend in the x direction.

A first interlayer insulating layer 113 may be arranged on the first electrode CE1 and a plurality of lower gate electrodes. The first interlayer insulating layer 113 may include an inorganic insulating layer including an inorganic insulating material such as silicon oxide, silicon nitride, and/or silicon oxynitride and may have a single-layered or a multi-layered structure, each layer therein including at least one selected from the materials described above.

Oxide semiconductor patterns may be arranged on the first interlayer insulating layer 113. The oxide semiconductor pattern may include an oxide-based semiconductor material, for example, Zn oxide, In—Zn oxide, Ga—In—Zn oxide, etc. According to some embodiments, the oxide semiconductor pattern may include an In—Ga—Zn—O (IGZO) semiconductor, an In—Sn—Zn—O (ITZO) semiconductor, or an In—Ga—Sn—Zn—O (IGTZO) semiconductor, in which a metal, such as In, Ga, or Sn is included in ZnO.

The oxide semiconductor pattern may include a second semiconductor layer A2 of the second transistor T2, a third semiconductor layer A3 of the third transistor T3, a fourth semiconductor layer A4 of the fourth transistor T4, a fifth semiconductor layer A5 of the fifth transistor T5, a sixth semiconductor layer A6 of the sixth transistor T6, a seventh semiconductor layer A7 of the seventh transistor T7, and a first initialization voltage line VL1.

The second semiconductor layer A2 may include a second channel area C2 and a first area and a second area B2 and D2 arranged at opposing sides of the second channel area C2. The first and second areas B2 and D2 of the second semiconductor layer A2 may be conductive areas and may have a higher electrical conductivity than the second channel area C2. One of the first and second areas B2 and D2 may be a source area, and the other thereof may be a drain area.

The third semiconductor layer A3 may include a third channel area C3 and a first area and a second area B3 and D3 arranged at opposing sides of the third channel area C3. The first and second areas B3 and D3 of the third semiconductor layer A3 may be conductive areas and may have a higher electrical conductivity than the third channel area C3. One of the first and second areas B3 and D3 may be a source area, and the other thereof may be a drain area.

The fourth semiconductor layer A4 may include a fourth channel area C4 and a first area and a second area B4 and D4 arranged at opposing sides of the fourth channel area C4. The first and second areas B4 and D4 of the fourth semiconductor layer A4 may be conductive areas and may have a higher electrical conductivity than the fourth channel area C4. One of the first and second areas B4 and D4 may be a source area, and the other thereof may be a drain area.

The fifth semiconductor layer A5 may include a fifth channel area C5 and a first area and a second area B5 and D5 arranged at opposing sides of the fifth channel area C5. The first and second areas B5 and D5 of the fifth semiconductor layer A5 may be conductive areas and may have a higher electrical conductivity than the fifth channel area C5. One of the first and second areas B5 and D5 may be a source area, and the other thereof may be a drain area.

The sixth semiconductor layer A6 may include a sixth channel area C6 and a first area and a second area B6 and D6 arranged at opposing sides of the sixth channel area C6. The first and second areas B6 and D6 of the sixth semiconductor layer A6 may be conductive areas and may have a higher electrical conductivity than the sixth channel area C6. One of the first and second areas B6 and D6 may be a source area, and the other thereof may be a drain area.

The seventh semiconductor layer A7 may include a seventh channel area C7 and a first area and a second area B7 and D7 arranged at opposing sides of the seventh channel area C7. The first and second areas B7 and D7 of the seventh semiconductor layer A7 may be conductive areas and may have a higher electrical conductivity than the seventh channel area C7. One of the first and second areas B7 and D7 may be a source area, and the other thereof may be a drain area.

The second semiconductor layer A2 and the fifth semiconductor layer A5 may be connected and integrally formed with each other as a single unitary an indivisible part. The third semiconductor layer A3, the fourth semiconductor layer A4, the sixth semiconductor layer A6, and the first initialization voltage line VL1 may be connected and integrally formed with each other as a single unitary an indivisible part.

According to an embodiment, as described above, the display apparatus 1 may include the component 20, and the component 20 may include an IR sensor transmitting/receiving IR rays. In such an embodiment, the IR rays may affect the transistors included in the sub-pixel circuit.

According to an embodiment, the second to seventh transistors T2 to T7 may include an oxide-based semiconductor. Because the second to seventh transistors T2 to T7 except for the first transistor T1 may include the oxide semiconductor, the second to seventh transistors T2 to T7 may have less leakage current and greater durability against the IR rays, compared with a transistor including a silicon-based semiconductor.

In such an embodiment, the first transistor T1 may include a silicon-based semiconductor. Because the first transistor T1 may include the silicon-based semiconductor, a gate voltage applied to the first gate electrode G1 through hydrogen injection/ejection may have an increased driving range. By increasing the driving range of the gate voltage applied to the first gate electrode G1, gradation of light emitted from the display element may be relatively more finely adjusted.

In such an embodiment, as described above, the first gate electrode G1 of the first transistor T1 may be arranged below the first semiconductor layer A1. Thus, the first transistor T1 may be protected from the IR rays emitted below the display panel 10.

That is, in the display apparatus 1 according to an embodiment, the first transistor T1 may include a silicon-based semiconductor, and thus, compared to a case where all of the transistors included in the sub-pixel circuit include an oxide-based semiconductor, the gradation may be more finely expressed. Also, because all of the second to seventh transistors T2 to T7, except for the first transistor T1, which is a driving transistor, may include the oxide-based semiconductor, and the first gate electrode G1 of the first transistor T1 may be arranged below the first semiconductor layer A1, the display apparatus 1 may become durable against IR rays which may occur when the component 20 is provided.

Referring to FIGS. 5 to 12 again, a second gate insulating layer 115 may be arranged on the oxide semiconductor pattern described above. The second gate insulating layer 115 may include an inorganic insulating layer including an inorganic insulating material such as silicon oxide, silicon nitride, and/or silicon oxynitride and may have a single-layered or a multi-layered structure, each layer therein including at least one selected form the materials described above.

A second electrode CE2, an upper emission control line EMb, a first upper gate line GL1b, and a second upper gate line GL2b may be arranged on the second gate insulating layer 115. Each of the upper emission control line EMb, the first upper gate line GL1b, and the second upper gate line GL2b may extend in the x direction.

The second electrode CE2, the upper emission control line EMb, the first upper gate line GL1b, and the second upper gate line GL2b may include Al, Pt, Pd, Ag, Mg, Au, Ni, Nd, Ir, Cr, Li, Ca, Mo, Ti, W, and/or Cu and may include a single layer or layers, each layer therein including at least one selected from the materials described above.

The second electrode CE1 may be electrically connected to the first gate electrode G1 through a first contact hole CNT1. The second electrode CE2 may be provided with a hole CE2OP defined therethrough to expose a portion of the second electrode CE2. The hole CE2OP may be entirely surrounded by a material portion included in the second electrode CE2 in a plan view. The second electrode CE2 may have a doughnut shape in the plan view. The second electrode CE2 may be an upper electrode of the capacitor Cst. The first electrode CE1 and the second electrode CE2 may be included in a first capacitor Cst1 (see FIG. 13).

The upper emission control line EMb may include a fifth upper gate electrode G5b and a sixth upper gate electrode G6b. The first upper gate line GL1b may include a second upper gate electrode G2b and a third upper gate electrode G3b. The second upper gate line GL2b may include a seventh upper gate electrode G7b and a fourth upper gate electrode G4b.

The first upper gate line GL1b may be electrically connected to the first lower gate line GL1a through a thirteenth contact hole CNT13. The second upper gate line GL2b may be electrically connected to the second lower gate line GL2a through a fourteenth contact hole CNT14. Although not shown, the upper emission control line EMb may be electrically connected to the lower emission control line EMa through a predetermined contact hole.

Accordingly, the second gate electrode G2 of the second transistor T2 may include the second lower gate electrode G2a and the second upper gate electrode G2b. The third gate electrode G3 of the third transistor T3 may include the third lower gate electrode G3a and the third upper gate electrode G3b. The fourth gate electrode G4 of the fourth transistor T4 may include the fourth lower gate electrode G4a and the fourth upper gate electrode G4b. The fifth gate electrode G5 of the fifth transistor T5 may include the fifth lower gate electrode G5a and the fifth upper gate electrode G5b. The sixth gate electrode G6 of the sixth transistor T6 may include the sixth lower gate electrode G6a and the sixth upper gate electrode G6b. The seventh gate electrode G7 of the seventh transistor T7 may include the seventh lower gate electrode G7a and the seventh upper gate electrode G7b.

The second to seventh transistors T2 to T7 may respectively include the second to seventh lower gate electrodes G2a to G7a therebelow, and thus, may block the IR rays irradiated below the display panel 10.

A second interlayer insulating layer 117 may be arranged on the second electrode CE2, the upper emission control line EMb, the first upper gate line GL1b, and the second upper gate line GL2b. The second interlayer insulating layer 117 may include an inorganic insulating layer including an inorganic insulating material such as silicon oxide, silicon nitride, and/or silicon oxynitride and may have a single-layered or a multi-layered structure, each layer therein including at least one selected from the materials described above.

A first conductive pattern CP1, a second conductive pattern CP2, a third conductive pattern CP3, a fourth conductive pattern CP4, a fifth conductive pattern CP5, a sub-voltage line PL′, and a second initialization voltage line VL2 may be arranged on the second interlayer insulating layer 117.

The first conductive pattern CP1, the second conductive pattern CP2, the third conductive pattern CP3, the fourth conductive pattern CP4, the fifth conductive pattern CP5, the sub-voltage line PL′, the second initialization voltage line VL2, and the second interlayer insulating layer 117 may include Al, Pt, Pd, Ag, Mg, Au, Ni, Nd, Ir, Cr, Li, Ca, Mo, Ti, W, and/or Cu and may include a single layer or layers, each layer therein including at least one selected from the materials described above.

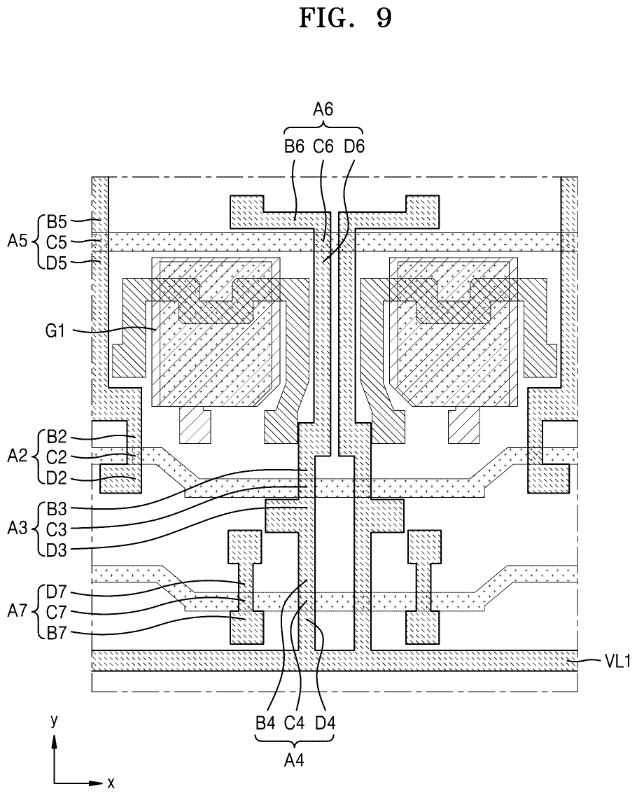

The first conductive pattern CP1 may electrically connect a data line DL with the second semiconductor layer A2. The first conductive pattern CP1 may contact a portion (for example, D2 of FIG. 9) of the first semiconductor layer A1 through a fourth contact hole CNT4 and may contact the data line DL above the first conductive pattern CP1 through a predetermined contact hole (not shown).

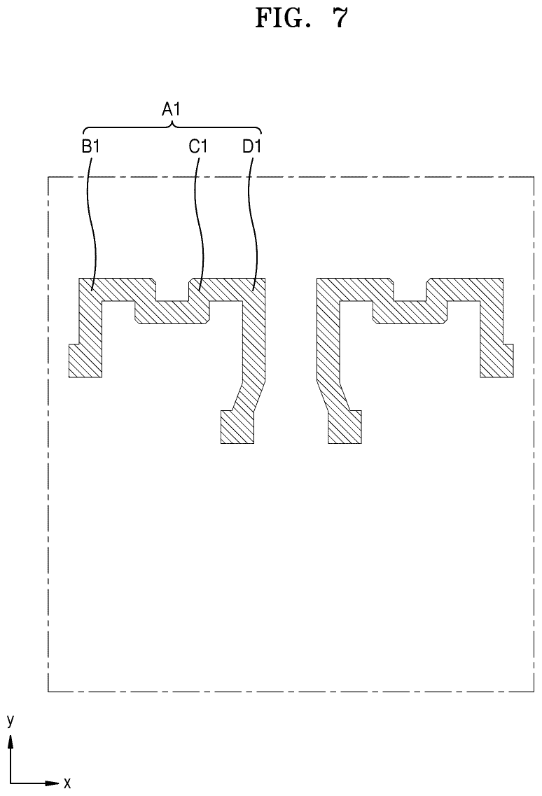

The second conductive pattern CP2 may electrically connect the second semiconductor layer A2 with the first semiconductor layer A1. The second conductive pattern CP2 may contact a portion (for example, B2 of FIG. 9) of the second semiconductor layer A2 through a fifth contact hole CNT5 and may contact a portion (for example, B1 of FIG. 7) of the first semiconductor layer A1 through a sixth contact hole CNT6.

The third conductive pattern CP3 may electrically connect the second electrode CE2 with the third semiconductor layer A3. The third conductive pattern CP3 may contact the second electrode CE2 through a second contact hole CNT2 and may contact a portion (for example, D3 of FIG. 9) of the third semiconductor layer A3 through a ninth contact hole CNT9.

The fourth conductive pattern CP4 may electrically connect the first semiconductor layer A1 with the third semiconductor layer A3. The fourth conductive pattern CP4 may contact a portion (for example, D1 of FIG. 7) of the first semiconductor layer A1 through a seventh contact hole CNT7 and may contact a portion (for example, B3 of FIG. 9) of the third semiconductor layer A3 through an eighth contact hole CNT8.

The fifth conductive pattern CP5 may electrically connect the seventh semiconductor layer A7 with the sixth semiconductor layer A6. The fifth conductive pattern CP5 may contact a portion (for example, B7 of FIG. 9) of the seventh semiconductor layer A7 through an eleventh contact hole CNT11 and may contact a portion (for example, B6 of FIG. 9) of the sixth semiconductor layer A6 through a twelfth contact hole CNT12.

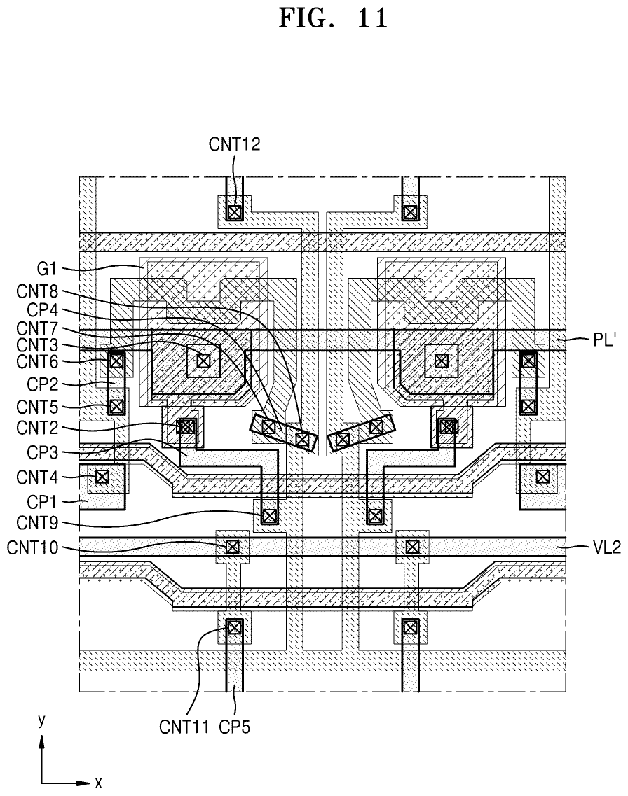

Although not shown in FIG. 11, the sub-voltage line PL′ may be electrically connected to a driving voltage line PL and may receive a first power voltage ELVDD. The sub-voltage line PL′ may contact the first electrode CE1 through the third contact hole CNT3. The third contact hole CNT3 may overlap the hole CE2OP of the second electrode CE2. The second initialization voltage line VL2 may be electrically connected to a portion (for example, D7 of FIG. 9) of the seventh semiconductor layer A7 through a tenth contact hole CNT10.

A first organic insulating layer 119 may be arranged on the first to fifth conductive patterns CP1 to CP5. The first organic insulating layer 119 may include an organic material, such as acryl, benzocyclobutene (BCB), PI, or hexamethyldisiloxane (HMDSO).

The data line DL and the driving voltage line DL may be arranged on the first organic insulating layer 119. The data line DL and the driving voltage line DL may include Al, Pt, Pd, Ag, Mg, Au, Ni, Nd, Ir, Cr, Li, Ca, Ti, and/or W. According to some embodiments, the driving voltage line PL may include a triple-layered structure including a Ti layer, an Al layer, and a Ti layer. The data line DL may contact the first conductive pattern CP1 through a contact hole (not shown), and the driving voltage line PL may contact the sub-voltage line PL′ through a contact hole (not shown).

A second organic insulating layer 122 may be arranged on the data line DL and the driving voltage line PL. The second organic insulating layer 122 may include an organic material, such as acryl, BCB, PI, or HMDSO.

A display element 200 may be arranged on the second organic insulating layer 122. The display element may include an organic light-emitting diode OLED. The display element 200 may include an anode 210, an intermediate layer 220 including an emission layer, and a cathode 230.

The anode 210 may include a transflective electrode or a reflection electrode. According to some embodiments, the anode 210 may include a reflective layer including Ag, Mg, Al, Pt, Pd, Au, Ni, Nd, Ir, Cr, and a compound thereof, and a transparent or semi-transparent electrode layer on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). According to some embodiments, the anode 210 may include ITO/Ag/ITO. The anode 210 may be electrically connected to a portion of a sub-pixel circuit through a contact hole (not shown).

A pixel-defining layer 123 may be arranged on the second organic insulating layer 122. In an embodiment, the pixel-defining layer 123 may increase a distance between an edge of the anode 210 and the cathode 230 above the anode 210, and thus, may prevent the occurrence of arcs, etc. at the edge of the anode 210.

The pixel-defining layer 123 may be formed by spin coating, etc. by using at least one organic insulating material selected from PI, polyamide, acryl resins, BCB, and phenol resins. The pixel-defining layer 123 may include an organic insulating material. Alternatively, the pixel-defining layer 123 may include an inorganic insulating material, such as silicon nitride, silicon oxynitride, or silicon oxide. Alternatively, the pixel-defining layer 123 may include an organic insulating material and an inorganic insulating material. According to some embodiments, the pixel-defining layer 123 may include a light-shielding material and may be provided in a black color. The light-shielding material may include a resin or paste including carbon black, a carbon nano-tube, and a black dye, a metal particle, such as Ni, Al, Mo, and an alloy thereof, a metal oxide particle (for example, chromium oxide), a metal nitride particle (for example, chromium nitride), or the like. In an embodiment where the pixel-defining layer 123 includes the light-shielding material, reflection of external light due to metal structures arranged below the pixel-defining layer 123 may be reduced.

The intermediate layer 220 may be arranged in an opening defined or formed in the pixel-defining layer 123. The intermediate layer 220 may include an organic emission layer. The organic emission layer may include an organic material including a fluorescent or phosphorescent material for emitting red, green, blue, or white light. The organic emission layer may include a low molecular-weight organic material or a high molecular-weight organic material. Also, a functional layer, such as a hole transport layer (HTL), a hole injection layer (HIL), an electron transport layer (ETL), or an electron injection layer (EIL), may be selectively further arranged above and below the organic emission layer.

The intermediate layer 220 may be arranged to correspond to each of the plurality of anodes 210. However, the intermediate layer 220 is not limited thereto. The intermediate layer 220 may be integrally or commonly formed over the plurality of anodes 210. As described above, the intermediate layer 220 may be variously modified.

The cathode 230 may include a transflective electrode or a reflection electrode. According to some embodiments, the cathode 230 may include a transparent or semi-transparent electrode and may include a metal thin-film having a low work function, such as Li, Ca, LiF/Ca, LiF/Al, Al, Ag, Mg, and a compound thereof. Also, a transparent conductive oxide (TCO) layer including ITO, IZO, ZnO, In₂O₃, or the like may further be arranged above the metal thin-film. The cathode 230 may be arranged in the entire display area DA and may be arranged above the intermediate layer 220 and the pixel-defining layer 123. The cathode 230 may be integrally or commonly formed over a plurality of the display element 200 and may correspond to the plurality of anodes 210.

The display element 200 may be covered by an encapsulation layer (not shown). The encapsulation layer may include at least one organic encapsulation layer and at least one inorganic encapsulation layer. The at least one inorganic encapsulation layer may include at least one inorganic material from aluminum oxide, titanium oxide, tantalum oxide, hafnium oxide, zinc oxide, silicon oxide, silicon nitride, and silicon oxynitride. The at least one inorganic encapsulation layer may include a single layer or layers, each layer therein including at least one selected from the materials described above. The at least one organic encapsulation layer may include a polymer-based material. The polymer-based material may include acryl-based resins, such as polymethylmethacrylate and polyacrylic acid, epoxy-based resins, PI, polyethylene, etc. According to an embodiment, the at least one organic encapsulation layer may include acrylate polymers.

FIG. 13 is a schematic cross-sectional view of the display apparatus taken along line II-II′ of FIG. 5. The second electrode CE2 may be electrically connected to the first gate electrode G1 through the second contact hole CNT2, and the sub-voltage line PL′ may be electrically connected to the first electrode CE1 through the third contact hole CNT3. Accordingly, the gate voltage of the first transistor T1 may be applied to the first gate electrode G1 and the second electrode CE2, and the first power voltage ELVDD may be applied to the first electrode CE1 and the sub-voltage line PL′.

The first electrode CE1 and the second electrode CE2 may form or collectively define the first capacitor Cst1, the first gate electrode G1 and the first electrode CE1 may form or collectively define the second capacitor Cst2, and the second electrode CE2 and the sub-voltage line PL′ may form or collectively define the third capacitor Cst3. As described above, through the contact holes, a same voltage may be applied to the first gate electrode G1 and the second electrode CE2, and a same voltage may be applied to the first electrode CE1 and the sub-voltage line PL′. Accordingly, the first capacitor Cst1, the second capacitor Cst2, and the third capacitor Cst3 may be connected in parallel with each other. The first to third capacitors Cst1 to Cst3 connected in parallel with each other may form the capacitor Cst described above.

The display apparatus 1 according to an embodiment may include the first to third capacitors Cst1 to Cst3 connected in parallel with each other, and thus, a structure in which no storage capacitor Cst is provided, according to an embodiment, may be compensated for.

The invention should not be construed as being limited to the embodiments set forth herein. Rather, these embodiments are provided so that this disclosure will be thorough and complete and will fully convey the concept of the invention to those skilled in the art. For example, a method of manufacturing the display apparatus may also be included in the scope of the disclosure.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a first transistor including a first semiconductor layer including a silicon semiconductor, and a first gate electrode below the first semiconductor layer, wherein the first transistor controls a magnitude of a driving current flowing to a display element;
a data line which transmits a data voltage;
a second transistor including a second semiconductor layer including an oxide semiconductor, wherein the second transistor connects the data line to the first transistor in response to a scan signal; and
a first capacitor including a first electrode and a second electrode, wherein the first electrode is disposed on the first semiconductor layer, and the second electrode at least partially overlaps the first electrode.

2. The display apparatus of claim 1, wherein the second electrode is electrically connected to the first gate electrode.

3. The display apparatus of claim 2, further comprising:
a sub-voltage line disposed on the second electrode and electrically connected to the first electrode.

4. The display apparatus of claim 3, wherein the first gate electrode, the first electrode, the second electrode, and the sub-voltage line at least partially overlap each other.

5. The display apparatus of claim 3, further comprising:
a second capacitor including the first gate electrode and the first electrode; and
a third capacitor including the second electrode and the sub-voltage line,
wherein the first capacitor, the second capacitor, and the third capacitor are connected in parallel with each other.

6. The display apparatus of claim 1, wherein the second transistor further includes:
a second lower gate electrode below the second semiconductor layer; and
a second upper gate electrode above the second semiconductor layer.

7. The display apparatus of claim 6, wherein
the second lower gate electrode is disposed in a same layer as a layer in which the first electrode is disposed, and
the second upper gate electrode is disposed in a same layer as a layer in which the second electrode is disposed.

8. The display apparatus of claim 1, further comprising:
a display panel including a display area and a non-display area outside the display area, wherein the display area includes a first display area and a second display area at least partially surrounded by the first display area, and the first and second transistors are disposed in the display area; and
a component disposed below the display panel to correspond to the second display area.

9. The display apparatus of claim 8, further comprising:
a plurality of first display elements disposed in the first display area;
a plurality of second display elements disposed in the second display area;
a plurality of second sub-pixel circuits electrically connected to the plurality of second display elements, respectively; and
a plurality of connection lines electrically connecting the plurality of second display elements with the plurality of second sub-pixel circuits, respectively,
wherein the plurality of second sub-pixel circuits are disposed between the first display area and the second display area or in the non-display area.

10. The display apparatus of claim 1, further comprising:
an emission control line which transmits an emission control signal;
an initialization voltage line which transmits an initialization voltage;
a fifth transistor which connects a driving voltage line to a side of the first semiconductor layer in response to the emission control signal;
a sixth transistor which connects another side of the first semiconductor layer to an anode of the display element in response to the emission control signal; and
a seventh transistor which connects the initialization voltage line to the anode of the display element in response to another scan signal.

11. The display apparatus of claim 10, wherein
the fifth transistor includes a fifth semiconductor layer,
the sixth transistor includes a sixth semiconductor layer,
the seventh transistor includes a seventh semiconductor layer, and
each of the fifth to seventh semiconductor layers includes the oxide semiconductor.

12. A display apparatus comprising:
a display panel including a display area and a non-display area outside the display area, wherein the display area includes a first display area and a second display area at least partially surrounded by the first display area; and
a component disposed below the display panel to correspond to the second display area,
wherein the display panel includes:
a first transistor including a first semiconductor layer including a silicon semiconductor, wherein the first transistor controls a magnitude of a driving current flowing to a display element;
a data line which transmits a data voltage;
a second transistor including a second semiconductor layer including an oxide semiconductor, wherein the second transistor connects the data line to the first transistor in response to a scan signal; and
a first capacitor including a first electrode and a second electrode, wherein the first electrode is disposed on the first semiconductor layer, and the second electrode is spaced apart from the first electrode.

13. The display apparatus of claim 12, wherein the first transistor further includes a first gate electrode below the first semiconductor layer.

14. The display apparatus of claim 13, further comprising:
a sub-voltage line disposed on the second electrode and electrically connected to the first electrode.

15. The display apparatus of claim 14, wherein the sub-voltage line is electrically connected to a driving voltage line.

16. The display apparatus of claim 14, further comprising:
a second capacitor including the first gate electrode and the first electrode; and
a third capacitor including the second electrode and the sub-voltage line.

17. The display apparatus of claim 13, further comprising:
an emission control line which transmits an emission control signal;
a first initialization voltage line which transmits a first initialization voltage;
a second initialization voltage line which transmits a second initialization voltage;
a fifth transistor which connects a driving voltage line to a side of the first semiconductor layer in response to the emission control signal;
a sixth transistor which connects another side of the first semiconductor layer to an anode of the display element in response to the emission control signal; and
a seventh transistor which connects the second initialization voltage line to the anode of the display element in response to another scan signal.

18. The display apparatus of claim 17, wherein
the fifth transistor includes a fifth semiconductor layer,
the sixth transistor includes a sixth semiconductor layer,
the seventh transistor includes a seventh semiconductor layer, and
each of the fifth to seventh semiconductor layers includes the oxide semiconductor.

19. The display apparatus of claim 18, further comprising:
a third transistor including a third semiconductor layer having a side connected to the first gate electrode and another side connected to the sixth semiconductor layer; and
a fourth transistor including a fourth semiconductor layer having a side connected to the first gate electrode and another side connected to the first initialization voltage line,
wherein each of the third semiconductor layer and the fourth semiconductor layer includes the oxide semiconductor.

20. The display apparatus of claim 19, wherein the third semiconductor layer, the fourth semiconductor layer, and the sixth semiconductor layer are integrally formed with each other as a single unitary and indivisible part.
